(19) United States
(12) Patent Application Publication
(10) Pub. No.: US 2024/0349617 A1
(43) Pub. Date: Oct. 17, 2024

(54) ELECTRONIC DEVICE AND ASSOCIATED SYSTEM, IN PARTICULAR MEMORY, LOGIC DEVICE OR NEUROMORPHIC DEVICE

(71) Applicants: Commissariat à l'énergie atomique et aux énergies alternatives, Paris (FR); THALES, Courbevoie (FR); Centre national de la recherche scientifique, Paris (FR); UNIVERSITE GRENOBLE ALPES, Saint Martin D'Heres (FR)

(72) Inventors: Jean-Philippe ATTANE, Grenoble (FR); Laurent VILA, Grenoble (FR); Manuel BIBES, Palaiseau (FR)

(73) Assignees: Commissariat à l'énergie atomique et aux énergies alternatives, Paris (FR); THALES, Courbevoie (FR); Centre national de la recherche scientifique, Paris (FR); UNIVERSITE GRENOBLE ALPES, Saint Martin D'Heres (FR)

(21) Appl. No.: 18/294,849

(22) PCT Filed: Aug. 4, 2022
(86) PCT No.: PCT/EP2022/072003

§ 371 Date: Feb. 2, 2024

(30) Foreign Application Priority Data
Aug. 6, 2021 (FR) FR2108563

(51) Int. Cl. H10N 50/20; G11C 11/16; H01L 29/66; H10N 50/85

(52) U.S. Cl. CPC H10N 50/20; G11C 11/161; H01L 28/55; H01L 29/66984; H10N 50/85

(57) ABSTRACT

The present invention relates to an electronic device comprising:
a first electrode comprising a contact,
a ferroelectric subassembly having a ferroelectric polarization,
a spin polarization subassembly which spin-polarizes an incident current and comprises a layer of ferromagnetic or ferrimagnetic material,
an interfacing subassembly which is arranged between the two subassemblies and converts the spin current into a charge current, the ferroelectric subassembly and the interfacing subassembly having a contact, and
a second electrode which comprises two contacts and delimits the polarization subassembly,
the contact of the first electrode changing the state of polarization by applying a potential difference between this contact and another contact.

The present invention relates to an electronic device, in particular a memory device, a logic device or a neuromorphic device.

The present invention relates to the field of ferroelectric devices such as memories, logic or neuromorphic devices, more particularly for information and communication technologies.

Ferroelectric materials carry a polarization. It is possible to encode information in the ferroelectric state, which can be written by applying a voltage. The above led to the emergence of ferroelectric memory/logic/neuromorphic devices.

An example of a known device using such effect is the Ferroelectric Random Access Memory (Fe-RAM). The Fe-RAM is a memory device similar to a Dynamic Random Access Memory (DRAM) to which a ferroelectric layer is added in order to obtain a property of non-volatility. The advantage of the Fe-RAM is to combine the speed of the random-access memory and the non-volatile features of the flash memory.

In the case of an Fe-RAM, the writing of information to be stored is performed by applying a voltage between the two faces of the ferroelectric layer. The information is thereby encoded in the polarized state of the ferroelectric layer.

The reading is performed by applying a voltage and by measuring the current produced. More precisely, a voltage pulse is applied between the two faces of the ferroelectric layer in order to attempt to switch the polarization from a first state to a second state, e.g. from the state “0” to the state “1”. If the Fe-RAM was already in the state “1”, the only output current read is related to the applied voltage pulse. If the Fe-RAM was initially in the state “0”, the current produced will be the sum between the current related to the voltage pulse and the depolarization current, related to the reversal of the polarization.

The read mechanism is thus destructive: The read erases the stored memory state, which involves rewriting the Fe-RAM by means of a particular architecture.

There is thus a need for a means of reading the polarization state of a ferroelectric layer using non-destructive mechanism, particularly for memory applications.

To this end, the description describes an electronic device comprising a stack of layers stacked along a direction of stacking, the stack of layers comprising a first electrode, comprising at least one electrical contact, a ferroelectric subassembly, the ferroelectric subassembly being in contact with the first electrode and having a ferroelectric polarization that can take a plurality of states. The stack of layers further comprises a spin-polarization subassembly, the spin-polarization subassembly being apt to spin-polarize a current flowing through the spin-polarization subassembly, at least one layer of the spin-polarization subassembly being made of ferromagnetic or ferrimagnetic material and an interfacing subassembly arranged between the ferroelectric subassembly and the spin-polarization subassembly, the interfacing subassembly being suitable for interfacing the spin-polarized current into the charge current, depending on the ferroelectric polarization state of the ferroelectric subassembly. The ferroelectric subassembly and the interfacing subassembly, respectively, have a part superimposed, along the direction of stacking, on the spin-polarization subassembly and a part not superimposed on the spin-polarization subassembly, at least one of the interfacing subassembly and the ferroelectric subassembly including a conductive layer apt to form an intermediate electrode, said intermediate electrode comprising an electrical contact for reading the polarization state of the ferroelectric subassembly. The stack of layers further comprises a second electrode comprising at least two electrical contacts for reading the state of polarization of the ferroelectric subassembly, the contacts each extending along a respective main direction, at least two main directions being non-parallel to each other, the second electrode delimiting the spin-polarization subassembly, the contact of the first electrode allowing the ferroelectric polarization state of the ferroelectric subassembly to be changed by the application of a difference of potential between said contact and at least one of the contacts of the second electrode or a difference of potential between said contact and the contact of the intermediate electrode.

According to other particular embodiments, the electronic device has one or a plurality of the following features, taken individually or according to all technically possible combinations:
the interfacing subassembly comprises at least one metal layer or one tunnel barrier or one spin-orbit layer, when the ferroelectric subassembly is all or in part conductive or semiconductive, or one metal layer or one tunnel barrier or one spin-orbit layer or one two-dimensional electron gas when the ferroelectric subassembly is insulating.
the ferroelectric subassembly comprising at least one semiconductive ferroelectric layer or a ferroelectric layer made of a conductive or semiconductive two-dimensional material, said interfacing subassembly being merged with the ferroelectric subassembly and including said at least one layer
the second electrode is a layer positioned over the spin-polarization subassembly.
the second electrode and the spin-polarization subassembly are merged.
the second electrode includes at least three contacts.
two contacts of the second electrode extend along parallel main directions, the third contact of the second electrode extending along a main direction substantially perpendicular to the main direction of the other two contacts of the second electrode.
the main directions of each contact of the intermediate electrode and the second electrode are all perpendicular to the direction of stacking.
the contact of the first electrode is either in a direction perpendicular to the direction of stacking or along a direction substantially parallel to the direction of stacking.
the interfacing subassembly includes at least one amongst a metal, a Weyl semi-metal, a two-dimensional material, a transition metal dichalcogenide and a topological insulator.
the interfacing subassembly comprises a barrier made of an insulating material, in particular an oxide.
the spin-polarization subassembly includes a ferromagnetic or ferrimagnetic metal alloy, a ferromagnetic or ferrimagnetic oxide, a magnetic semiconductor, a ferromagnetic or ferrimagnetic composite element with a plurality of ferromagnetic or ferrimagnetic and metallic layers, a Heusler alloy or a ferromagnetic or ferrimagnetic alloy containing rare earths.
the ferroelectric sub-stack comprises a ferroelectric material chosen from a material with a perovskite structure of the type ABO₃ with A and B cations, (HF₁₋ₓZRₓ)O₂, (HF₁₋ₓGAₓ)O₂ where x is comprised between 0 and 1, or HfO₂ doped with other elements such as Zr or Ga, or the alloys thereof, poly(vinylidene fluoride), a ferroelectric semiconductor, and a two-dimensional ferroelectric material.
the contacts perform the reading of the polarization state of the spin-polarization subassembly by the application of a reading voltage between two so-called read contacts chosen from the contact of the intermediate electrode and the contacts of the second electrode and by measuring the voltage between two of the other so-called read contacts or between one of said other so-called read contacts and a reference potential.

The description further describes a system, in particular a memory, a logic device or a neuromorphic device, including an electronic device.

The features and advantages of the invention will appear clearer upon reading the following description, given only as an example, but not limited to, and making reference to the enclosed drawings, wherein:

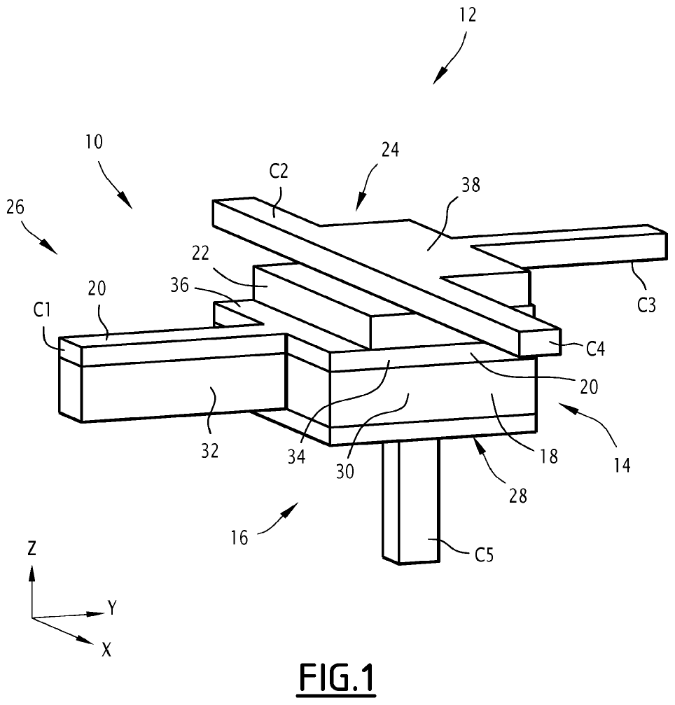

FIG. 1 is a schematic representation of an example of electronic device,

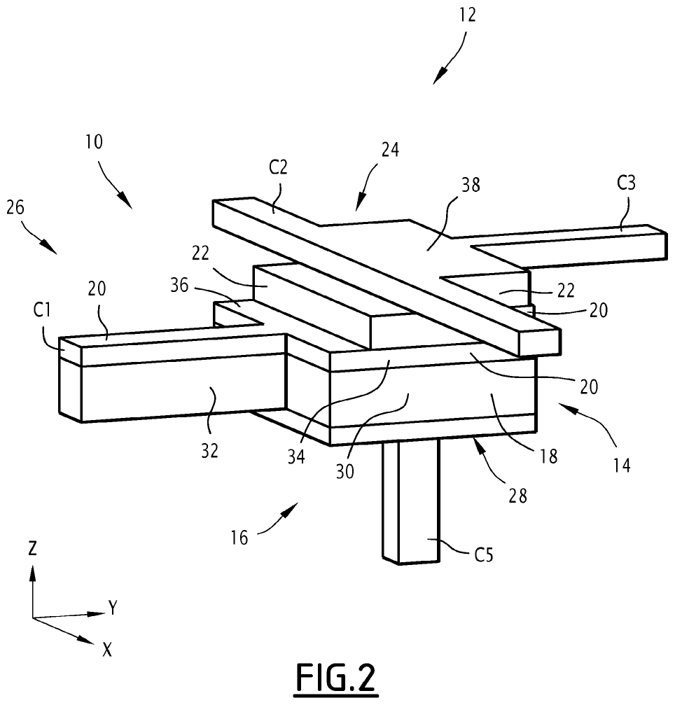

FIG. 2 is a schematic representation of another example of electronic device,

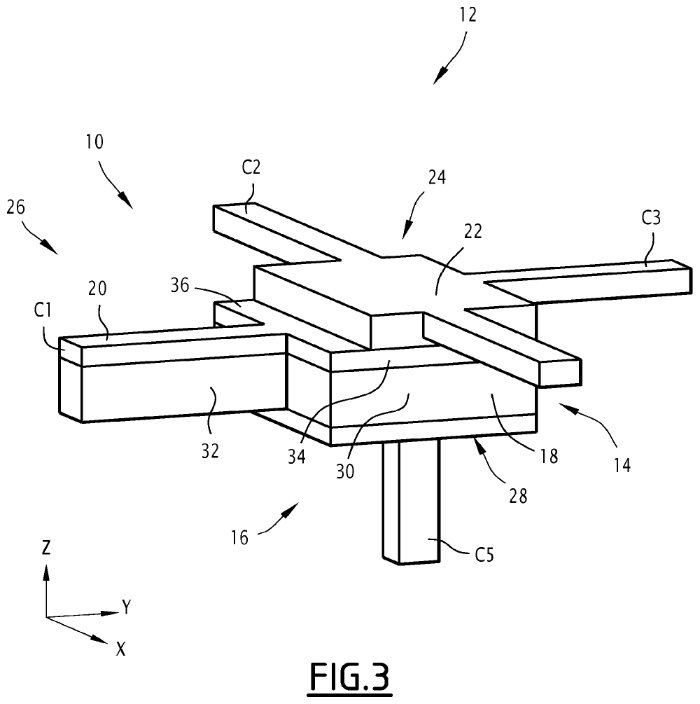

FIG. 3 is a schematic representation of another example of electronic device, and

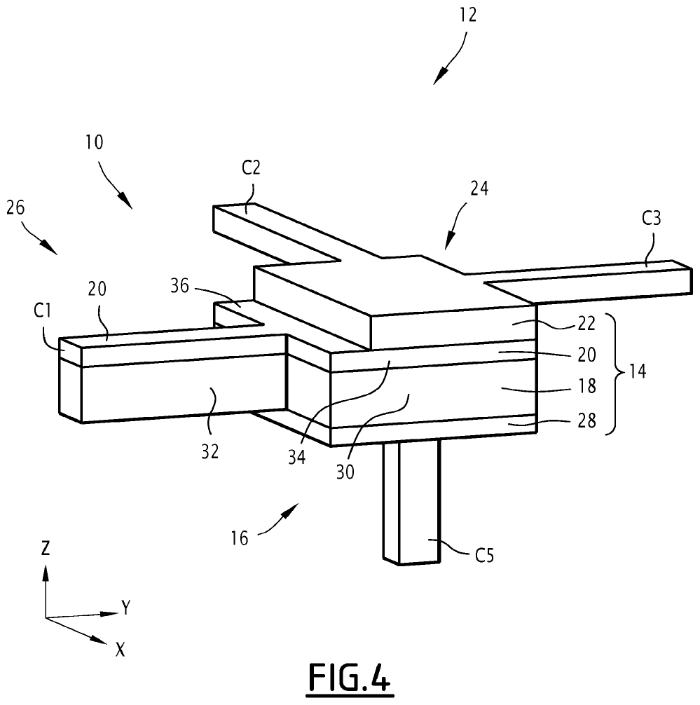

FIG. 4 is a schematic representation of another example of electronic device.

To simplify the description, a memory will be chosen as an example of application of the electronic device of the invention, knowing that such devices can also make it possible to produce logical or neuromorphic devices.

Thereby, FIG. 1 shows an electronic device 12 of a memory 10. The memory 10 further comprises a read unit and a write unit, the read and write units not being shown, so that FIG. 1 stays clear.

The electronic device 12 includes a stack of layers 14.

The layers of the stack 14 are layers stacked along a direction of stacking Z.

Two longitudinal directions are then defined which are perpendicular to the direction of stacking Z, a first longitudinal direction X and a second longitudinal direction Y. The two longitudinal directions X and Y are orthogonal to each other and chosen so that the axis of reference X, Y and Z is direct. The two directions X, Y define a plane parallel to the plane of the layers of the stack.

With reference to FIG. 1, the relative notions of bottom and top with respect to the direction of stacking Z, are also defined. A layer is located lower than another layer (below) if the layer is lower in the representation on the sheet of FIG. 1, while it should be understood that the stacking can have the opposite direction along the direction Z.

Finally, the thickness of a layer is defined as the dimension along the direction of stacking Z of the layer, i.e. the distance between the two faces thereof.

In the example shown in FIG. 1, the stack of layers 14 comprises from the bottom upwards, a first electrode 16, a ferroelectric subassembly 18, an interfacing subassembly 20, a spin-polarization subassembly 22 and a second electrode 24.

Hereinafter, for convenience, the first electrode 16 is called the lower electrode and the second electrode 24 is called the upper electrode.

The electronic device 10 further includes an intermediate electrode 26, the intermediate electrode 26 comprising a contact, denoted by contact C1 in FIG. 1.

In the example described, the lower electrode 16 includes a contact, denoted by contact C5 in FIG. 1, and the upper electrode 24 includes in the present example, three contacts (but at least two contacts are sufficient), so that the electronic device 10 includes at least four contacts.

Then, hereinafter, the contact of the intermediate electrode 26 is called the first contact C1, the contacts of the upper electrode 24 are called the second contact C2, the third contact C3, the fourth contact C4, respectively, and the contact of the lower electrode 16 is called the fifth contact C5.

Each contact C1, C2, C3, C4 and C5 is an electrical contact.

In the representation of FIG. 1, each contact C1, C2, C3, C4 and C5 is represented in the form of a parallelepiped extending along a main direction.

Although this shape is non-limiting, each contact C1, C2, C3 and C4 has a respective main direction.

According to the example shown in FIG. 1, the lower electrode 16 includes the fifth contact C5 and a contact layer 28.

In a variant, the lower electrode 16 can include a plurality of contacts.

In the example described, the fifth contact C5 extends mainly along the direction of stacking Z.

In a variant, the fifth contact C5 extends along a direction substantially parallel to the direction of stacking Z.

In the present context, the expression “substantially” means an equality within 15°.

It will become clear hereinafter in the description that the fifth contact C5 makes it possible to modify the ferroelectric polarization state of the ferroelectric subassembly 18 by the application of a difference of potential between the contact C5 and at least one of the contacts C2, C3 or C4 of the second electrode 24.

Alternatively, the fifth contact C5 makes it possible to modify the ferroelectric polarization state of the ferroelectric subassembly 18 by the application of a difference of potential between this contact C5 and the first contact C1 of the intermediate electrode 26.

The thickness of contact layer 28 is typically comprised between 0.2 nanometer (nm) and 100 nm.

According to the example described, the lower electrode 16 is made of a metallic material.

In a variant, the lower electrode 16 is made of a doped semiconductor material.

For each electrode 16 or 24, the contact of the electrodes can be made in the same layer as the electrode or made independently of the layer forming the electrode and can either be made or not be made of the same material as the latter.

The ferroelectric subassembly 18 has an apparent ferroelectric polarization that can take a plurality of states, i.e. the polarization has a non-linear relationship between the voltage V applied between the faces thereof and the apparent stored charge Q following a hysteresis cycle, resulting in at least two remanent states.

In the example shown in FIG. 1, the ferroelectric subassembly 18 is in contact with the lower electrode 16.

The ferroelectric subassembly 18 consists of a single- or multi-layer including one or a plurality of materials providing ferroelectric properties to the resulting stack.

A plurality of examples of ferroelectric material that can be used to produce at least one layer of the ferroelectric subassembly 18 are now described.

According to a first example, the ferroelectric material is an oxide having a perovskite structure of the ABO₃ type (where A and B are cations).

Thereby, the ferroelectric material present in the ferroelectric subassembly 18 is e.g. made of BaTiO₃, PZT (i.e. PbZr₁₋ₓTiₓO₃ with x varying between 0 and 1), of PMN-PT (i.e. [1-x]Pb (mg_{1/3}NB_{2/3})O₃-xPbTiO₃ with x varying between 0 and 1), of BiFeO₃ (doped, if appropriate, e.g. with a rare earth on the Bi site, or with Mn on the Fe site), SrTiO₃ (doped, if appropriate), of KTiO₃ (doped, if appropriate), of Pr_{0.7}Ca_{0.3}MnO₃ (doped, if appropriate) or of YMnO₃ (doped, if appropriate).

According to a second example, the ferroelectric material is (Hf₁₋ₓZrₓ)O₂ or (Hf₁₋ₓGaₓ)O₂ (x varying between 0 and 1), or HfO₂ doped with other elements, or the alloys thereof.

The ferroelectric material can also be poly(vinylidene fluoride).

In such a second example, the ferroelectric material does not have the perovskite structure, unlike in the first example.

According to a third example, the ferroelectric material is a ferroelectric semiconductor. GeTe, doped, if appropriate, or AlScN, are examples of ferroelectric semiconductor materials.

According to a fourth example, the ferroelectric material is a two-dimensional ferroelectric material. SnTe or CuInP₂S₆ are examples of two-dimensional ferroelectric materials.

In each of the above-mentioned examples, the ferroelectric material can be irradiated, annealed, doped or deposited on specific substrates so as to modulate the ferroelectric and transport properties thereof.

According to the example described, the coercive electric field of the ferroelectric element and the thickness thereof are sufficiently small for the polarization to be reversed at voltages compatible with microelectronic technologies, i.e. voltages below 10 volts (<10 V). A thickness of less than 150 nm and advantageously less than 50 nm in the aforementioned materials makes it possible to obtain such properties. The ferroelectric subassembly 18 is also resistant to cycling, typically apt to withstand at least 104 cycles.

The spin-polarization subassembly 22 includes at least one magnetic layer made of a ferromagnetic or ferrimagnetic material.

According to a first case, the magnetic material is a ferromagnetic or ferrimagnetic metal alloy composed of elements such as Co, Fe, B, Ni or Al.

According to a second case, the magnetic material is a ferromagnetic or ferrimagnetic oxide.

According to a third case, the magnetic material is a magnetic semiconductor.

According to a fourth case, the magnetic material is a composite ferromagnetic or ferrimagnetic element of the type [FM/M]ₙ/FM, i.e. a stack of a plurality of ferromagnetic or ferrimagnetic layers FM and metallic layers M coupled together.

The number n advantageously varies between 1 and 50.

The ferromagnetic or ferrimagnetic materials FM are e.g. the materials of the first three cases.

The metallic materials M are e.g. chosen from Al, Ta, Ru, Pt, W, Ir, Mo, Ti, Y and Au.

According to a fifth case, the magnetic material is a Heusler alloy.

As an example, the Heusler alloy is chosen from Cu₂MnAl, Cu₂MnIn, Cu₂MnSn, NfiMnAl, NfiMnIn, NfiMnSn, NfiMnSb, Ni₂MnGa, Co₂MnAl, Co₂MnSi, Co₂MnGa, Co₂MnGe, PD₂MnAl, PD₂MnIn, PD₂MnSn, PD₂MnSb, Co₂FeSi, Co₂FeAl, Fe₂Val, Mn₂VGA, Co₂FeGe, MnGa and MnGaRu.

According to a sixth case, the magnetic material is an alloy containing rare earths.

For example, the magnetic material is an alloy containing Nd, Sm, Eu, Gd, Tb, or Dy.

The spin-polarization subassembly 22 serves to spin-polarize the charge current flowing through the spin-polarization subassembly 22.

The spins within the spin-polarization subassembly 22 are advantageously polarized along the first longitudinal direction X.

In the case of a relatively large remanent magnetization, such a spin-polarization direction can be obtained by applying a magnetic field along the first longitudinal direction X, in order to saturate the magnetization.

For magnetically softer materials, it is possible to create an anisotropy in the plane, e.g. by using field annealing techniques, by playing on the shape anisotropy, by texturing the surface of the magnetic layer, or by using exchange coupling with an antiferromagnetic layer that is part of the spin-polarization subassembly 22.

Furthermore, the thickness of the ferromagnetic layer is small (typically less than 100 nm), so as to optimize the signal read by the read unit.

The spin-polarization subassembly 22 makes it possible to obtain a relatively high spin-polarization, preferentially greater than 0.1.

The ferroelectric subassembly 18 and the spin-polarization subassembly 22 are geometrically arranged in a particular way.

In the present case, the ferroelectric subassembly 18 has two parts 30 and 32.

The first part 30 is a part 30 superposed, along the direction of stacking Z, on the spin-polarization subassembly 22.

In the present case, the first part 30 is a parallelepipedal portion.

The second part 32 is a part 32 non-superposed on the spin-polarization subassembly 22.

In the present case, the second part 32 is a T-shaped portion, the horizontal bar of the T being in contact with the first part 30 and the vertical bar of the T being along the second longitudinal direction Y.

The interfacing subassembly 20 delimits the ferroelectric subassembly 18.

The interfacing subassembly 20 is arranged between the spin-polarization subassembly 22 and the ferroelectric subassembly 18. In the case where the ferroelectric subassembly 18 includes a semiconducting ferroelectric material or a two-dimensional ferroelectric material, said interfacing subassembly 20 can be merged with the ferroelectric subassembly 18.

According to the example shown in FIG. 1, the interfacing subassembly 20 has two parts 34 and 36.

The first part 34 of the interfacing subassembly 20 corresponds to the superposed part 30 of the ferroelectric subassembly 18.

In the case illustrated, the first part 34 is superposed on the superposed part 30 of the ferroelectric subassembly 18.

The second part 36 of the interfacing subassembly 20 corresponds to the non-superposed part 32 of the ferroelectric subassembly 18.

In the present case, the first part 34 is superimposed on the horizontal bar of the T of the non-superimposed part 32 of the ferroelectric subassembly 18.

In FIG. 1, the first part 34 of the interface subassembly 20 is thus superimposed on the spin-polarization subassembly 22 along the direction of stacking Z, whereas the second part 36 of the interface subassembly 20 is not superimposed on the spin-polarization subassembly 22.

Otherwise formulated, at least one of the interfacing subassembly 20 and the ferroelectric subassembly 18 includes a conductive layer apt to form the intermediate electrode 26, which electrode comprises the first contact C1 which is an electrical contact for reading the state of polarization of the ferroelectric subassembly 18.

According to a first example, the interfacing subassembly 20 consists of or includes a two-dimensional electron gas.

According to a second example, the interface subassembly 20 includes one or a plurality of interface layers serving to convert the spin current into a charge current.

It should be noted that the conversion of spin current into charge current in the interfacing subassembly 20 can be modulated by the ferroelectricity of the ferroelectric subassembly 18, and sufficiently high to minimize the energy consumption of the memory.

In particular, the interface subassembly 20 includes at least one layer with a strong spin-orbit effect, called the spin-orbit layer.

The spin-orbit layer has a relatively low thickness, typically less than or equal to 10.

The material used to produce the spin-orbit layer varies according to the case.

According to a first example, the material of the spin-orbit layer is a material displaying the spin Hall effect.

A material displaying the spin Hall effect is a material which can convert a charge current into a spin current, having a spin Hall effect angle typically greater than 5%

For example, the material displaying a spin-orbit spin Hall effect can be tantalum in the β phase (β-Ta) thereof, BiSb, β-tungsten (β-W), W or Pt.

According to another example, the material of the spin-orbit layer is Cu or Au doped with elements of the columns 3d, 4d, 5d, 4f, 5f of the periodic table, such as W, Ta, Bi, so as to obtain large spin-orbit effects, or a combination of elements 5d, such as PtW.

According to a second case, the material of the spin-orbit layer is a two-dimensional spin-orbit material.

As an example of the second case, the following materials can be cited: graphene, BiSe₂, BiS₂, BiSexTe₂₋ₓ (x varying between 0 and 2), BiS, TiS, WS₂, MoS₂, the TiSe₂, VSe₂, MoSe₂, B₂S₃, Sb₂S, T_{0.75}S, Re₂S₇, LaCPS₂, LaOAsS₂, ScOBiS₂, GaOBiS₂, AIOBiS₂, LaOSbS₂, BiOBiS₂, YOBIS₂, InOBiS₂, LaOBiSe₂, TiOBiS₂, CeOBiS₂, PrOBiS₂, NdOBiS₂, LaOBiS₂, or SrFBiS₂.

If appropriate, the above-mentioned materials can be doped.

According to a third case, the material of the spin-orbit layer is a topological insulator. A topological insulator is a material with an insulator strip structure, and which has metallic surface states.

For example, the material of the spin-orbit layer is Bi₂SE₃, BiSbTe, SbTe₃, HgTe or α-Sn.

According to a fourth case, the material of the spin-orbit layer is a Weyl semi-metal.

In such a case, the material of the spin-orbit layer is e.g. TaAs, TaP, NbAs, NbP, Na₃Bi, Cd₃As₂, WTe₂ or MoTe₂.

Furthermore, an irradiation of the material can be carried out with ions, such as He ions or Ar ions.

According to a fifth case, the material of the spin-orbit layer is a transition metal dichalcogenide and preferentially an ROCh₂ dichalcogenide. Indeed, such a material displays a good Rashba effect.

In such a formula, “R” is e.g. chosen from amongst La, Ce, Pr, Nd, Sr, Sr, Ga, Al, or In whereas “Ch” is chosen from amongst S, Se or Te.

In a variant or in addition, the interface layer includes one or a plurality of non-ferromagnetic metal layers so as to enhance the conversion of spin current into charge current.

For example, the interfacing layer can be made of a layer of Al, Y, Ru, Mg, Ta or Ti.

According to another variant compatible with the preceding embodiments, the interfacing layer comprises a barrier made of an insulating material, in particular an oxide.

Such a barrier can e.g. be made of MgO or Al₂O₃ and serves to improve the spin injection process, but also the properties of the signal to be read by the read unit.

In each of the preceding embodiments, the interface subassembly 20 is in contact with a face of the spin-polarization subassembly 22.

Furthermore, the interfacing subassembly 20 is suitable for inter-converting the spin-polarized current into a charge current, depending on the ferroelectric polarization state of the ferroelectric subassembly 18.

The upper electrode 24 includes a metal layer 38 and three contacts, namely the second contact C2, the third contact C3 and the fourth contact C4.

The metal layer 38 is in contact with the spin-polarization subassembly 22.

The three contacts C2, C3 and C4 are electrical contacts for reading the state of polarization of the ferroelectric subassembly 18.

According to the example described, the second contact C2 and the fourth contact C4 extend mainly along the same direction, namely the second longitudinal direction Y. The two contacts C2 and C4 are thus opposite each other.

The third contact C3 extends mainly along a direction perpendicular to the main direction of the contacts C2 and C4.

The third contact C3 is electrically connected to the metal layer 38.

In fact, the first contact C1 is positioned on the non-superposed part 32 and more precisely on the vertical bar of the T of the non-superposed part 32.

The first contact C1 electrically connects the interfacing subassembly 20, and in particular the first part 34 of the interfacing subassembly 20.

In addition, the first contact C1 is accessible from above since same is not covered by the spin-polarization subassembly 22.

The first contact C1 is an electrical contact for reading the state of polarization of the ferroelectric subassembly 18.

The operation of the memory 10 is now described.

During writing, the write unit charges the contact layer 28 of the lower electrode 16.

For example, the write unit is a transistor making it possible to charge the contact layer 28, either positively or negatively.

During reading, in a first method, the read unit applies a current (or a voltage) between the first contact C1 and the third contact C3.

Because of the particular arrangement shown in FIG. 1, the current injected between the first contact C1 and the third contact C3 flows entirely from the spin-polarization subassembly 22 to the interface subassembly 20.

The read unit then measures the voltage between the second contact C2 and the fourth contact C4, or between a contact amongst the second contact C2 and the fourth contact C4, and a reference electrical potential.

In a second method, reciprocal to the first, the read unit applies a current (or voltage) between the second contact C2 and the fourth contact C4. The read unit then measures the voltage between the first contact C1 and the third contact C3, or between a contact among the contact C1 and the third contact C3, and a reference electrical potential.

In the two methods, the current thus does not flow through the ferroelectric subassembly 18.

The measured voltage depends on the injected current and on the electric polarization along the direction of stacking Z of the ferroelectric subassembly 18, since the ferroelectric subassembly 18 controls electrically and in a non-volatile way, the interconversion of the spin current into the charge current.

The read unit is thus apt to measure the electric polarization of the ferroelectric sub-assembly 18 with a sub-unit for injecting current and a sub-unit for measuring voltage.

The measurement has the particularity of preserving the state of polarization of the ferroelectric sub-assembly 18 and is thus non-destructive.

The memory 10 is thus a non-destructive read memory.

Other embodiments of an electronic component 10 are conceivable with reference to FIGS. 2, 3 and 4.

In said figures, the elements common to the embodiment of FIG. 1 are not repeated, only the differences being emphasized.

In the case shown in FIG. 2, one of the electrical contacts extending along the direction perpendicular to the direction of the first and third contacts C1 and C3 is removed.

Herein, only the second contact C2 is kept.

In operation, the injection of the read current between the first and third contacts C1 and C3 entails a movement of charges through the second contact C2.

Instead of measuring the voltage like in the embodiment shown in FIG. 1, the read unit measures the movement of charges, e.g. by measuring the electrical potential of the second contact C2.

For FIG. 3, the second, third and fourth contacts C2, C3 and C4 are made in the spin-polarization subassembly 22, so that the upper electrode 38 and the spin-polarization subassembly 22 are merged.

Another embodiment of the memory will now be described with reference to FIG. 4.

The memory 10 shown in FIG. 4 corresponds to the combination of the memories 10 according to FIGS. 2 and 3 (contacts C2 and C3 made in the spin-polarization subassembly 22).

The electronic device 12 which has just been presented for an application to a memory 10 can further be used as a basic element of other systems and more particularly a logic device or a neuromorphic device. In the case of a neuromorphic device, the ferroelectric subassembly 18 is designed to have stable states of partial reversal of the apparent electric polarization. The write voltage and the time during which the voltage is applied make it possible to reach such states, which correspond to different read voltages.

The electronic device 12 can further be used as a basic element for a logic system. The read voltage of a first device is then connected to a second device to serve as a write voltage for the second device.

1. An electronic device comprising a stack of layers stacked along a direction of stacking, the stack of layers comprising:
a first electrode, comprising at least one electrical contact,
one ferroelectric subassembly, the ferroelectric subassembly being in contact with the first electrode and having a ferroelectric polarization which can take a plurality of states,
a spin-polarization subassembly, the spin-polarization subassembly being adapted to spin-polarize a current flowing through the spin-polarization subassembly, at least one layer of the spin-polarization subassembly being made of ferromagnetic or ferrimagnetic material,
an interfacing subassembly arranged between the ferroelectric subassembly and the spin-polarization subassembly, the interfacing subassembly being adapted to inter-convert the spin-polarized current into the charge current depending on the ferroelectric polarization state of the ferroelectric subassembly,
the ferroelectric subassembly and the interfacing subassembly, respectively, having a part superimposed along the direction of stacking, on the spin-polarization subassembly and a part not superimposed on the spin-polarization subassembly, at least one of the interfacing subassembly and the ferroelectric subassembly including a conductive layer suitable for forming an intermediate electrode, said intermediate electrode comprising an electrical contact for reading the state of polarization of the ferroelectric subassembly, and
a second electrode comprising at least two electrical contacts for reading the state of polarization of the ferroelectric subassembly, the contacts each extending along a respective main direction, at least two main directions being non-parallel to each other, the second electrode delimiting the spin-polarization subassembly,
the contact of the first electrode making it possible to change the ferroelectric polarization state of the ferroelectric subassembly by application of a difference of potential between the contact and at least one of the contacts of the second electrode or of a difference of potential between the contact and the contact of the intermediate electrode.

2. The device according to claim 1 wherein the interfacing subassembly comprises at least:
one metal layer or one tunnel barrier or one spin-orbit layer, when the ferroelectric subassembly is all or in part conductive or semiconductive, or
one metal layer or one tunnel barrier or one spin-orbit layer or one two-dimensional electron gas when the ferroelectric subassembly is insulating.

3. The device according to claim 2, wherein the ferroelectric subassembly comprises at least one semiconductive ferroelectric layer or a ferroelectric layer of conductive or semiconductive two-dimensional material, said interfacing subassembly being merged with the ferroelectric subassembly and including said at least one layer.

4. The device according to claim 1, wherein the second electrode is a layer positioned over the spin-polarization subassembly.

5. The device according to claim 1, wherein the second electrode and the spin-polarization subassembly are merged.

6. The device according to claim 1, wherein the second electrode has at least three contacts.

7. The device according to claim 6, wherein two contacts of the second electrode extend along parallel main directions, the third contact of the second electrode extending along a main direction substantially perpendicular to the main direction of the other two contacts of the second electrode.

8. The device according to claim 1, wherein the main directions of each contact of the intermediate electrode and the second electrode are all perpendicular to the direction of stacking.

9. The device according to claim 1, wherein the contact of the first electrode is either along a direction perpendicular to the direction of stacking or along a direction substantially parallel to the direction of stacking.

10. The device according to claim 1, wherein the interfacing subassembly includes at least one element chosen in the list consisting of a metal, a Weyl semi-metal, a two-dimensional material, a transition metal dichalcogenide and a topological insulator.

11. The device according to claim 1, wherein the interfacing subassembly comprises a barrier made of an insulating material, in particular an oxide.

12. The device according to claim 1, wherein the spin-polarization subassembly includes a ferromagnetic or ferrimagnetic metal alloy, a ferromagnetic or ferrimagnetic oxide, a magnetic semiconductor, a ferromagnetic or ferrimagnetic composite element with a plurality of ferromagnetic or ferrimagnetic and metallic layers, a Heusler alloy or a rare earth ferromagnetic or ferrimagnetic alloy.

13. The device according to claim 1, wherein the-ferroelectric sub-stack comprises a stack of a ferroelectric material chosen in the list consisting of amongst:
a material with a perovskite structure of the type ABO₃ with A and B cations,
(Hf₁₋ₓ)ZRₓ)O₂, (Hf₁₋ₓGAₓ)O₂ where x is comprised between 0 and 1, or HfO₂ doped with other elements such as Zr or Ga, or alloys thereof,
poly(vinylidene fluoride),
a ferroelectric semiconductor, and
a two-dimensional ferroelectric material.

14. The device according to claim 1, wherein the contacts perform the reading of the polarization state of the spin-polarization subassembly by application of a read voltage between two so-called read contacts chosen from the contact of the intermediate electrode and the contacts of the second electrode and by measuring the voltage between two of the other so-called read contacts or between one of said other so-called read contacts and a reference potential.

15. A system, in particular memory, logic device or neuromorphic device, including an electronic device according to claim 1.
